(19) United States
(12) Patent Application Publication
(10) Pub. No.: US 2007/0292312 A1
(43) Pub. Date: Dec. 20, 2007

(54) METHOD OF MANUFACTURE OF A PLATE OF RELEASABLE ELEMENTS AND ITS ASSEMBLY INTO A CASSETTE

(76) Inventors: Mark Bachman, Irvine, CA (US); Yuli Wang, Irvine, CA (US); Christopher E. Sims, Irvine, CA (US); Nancy Allbritton, Irvine, CA (US); Guann-Pyng Li, Irvine, CA (US)

Correspondence Address: ORRICK, HERRINGTON & SUTCLIFFE, LLP;IP PROSECUTION DEPARTMENT, 4 PARK PLAZA, SUITE 1600, IRVINE, CA, 92614-2558, US

(21) Appl. No.: 11/742,006

(22) Filed: Apr. 30, 2007

Related U.S. Application Data
(60) Provisional application No. 60/746,008, filed on Apr. 28, 2006.

(51) Int. Cl. B01L 3/02; G01N 35/00; G03F 7/038

(52) U.S. Cl. 422/82; 422/102; 422/50; 430/18; 430/270.1

(57) ABSTRACT

A plate manufactured to enable samples of cells, micro-organisms, proteins, DNA, biomolecules and other biological media to be positioned at specific locations or sites on the plate for the purpose of performing addressable analyses on the samples. Preferably, some or all of the sites are built from a removable material or as pallets so that a subset of the samples of interest can be readily isolated from the plate for further processing or analysis. The plate can contain structures or chemical treatments that enhance or promote the attachment and/or function of the samples, and that promote or assist in their analyses.

### CROSS-REFERENCE TO RELATED APPLICATIONS DATA

This application claims the benefit of U.S. provisional patent application No. 60/746,008, filed Apr. 28, 2006, which application are incorporated herein by reference.

### FIELD OF THE INVENTION

The present invention relates to a micropatterned plate with micro-pallets that facilitates addressable biochemical analysis and, more particularly, to a method of manufacture of a plate of releasable elements and its assembly into a cassette.

### BACKGROUND

Conventional systems allow for biological materials to be positioned in arrays on surfaces. Material can be placed by mechanically putting materials in specific locations (“spotting”), by building cavities to collect the material (micro-wells), by treating the surface in specific regions, or by combinations of these methods. Most of these techniques do not work well for living cells. Once positioned, samples are almost never removed for further analysis or processing.

Adherent cells are typically analyzed by plating them on a surface then looking for them using a microscope. The locations of the cells are random so that finding the cells can be a time consuming process. To speed this up, robotic systems that utilize machine vision are sometimes used to find the cells within the field of view of the microscope image. In some cases a subset of cells are isolated by the following method: A sacrificial base layer is placed over the plate. Cells are grown on the base layer. A high powered laser is used to cut a circle around the cells of interest, through the sacrificial layer. Cells can be isolated by peeling away the sacrificial layer, or by catapulting the cut material from plate using a high powered laser pulse, carrying the cell with it.

Nonadherent cells can be analyzed quickly using a flow cytometer that rapidly flows a stream of cells past a detector apparatus. Cells of interest can be sorted by a downstream electrostatic system that moves droplets into collection containers. This method will also work for other biological media such as proteins and DNA if they can be attached to small beads. This method does not work well for larger samples (such as multi-celled organisms) and is difficult to multiplex.

It is desirable to provide a plate of releasable elements, called “micropallets”, which can be used to perform biological and chemical assays and methods for manufacturing the plate.

### SUMMARY

The system and methods described herein provide a plate manufactured in such a way that samples such as single or multiple cells, micro-organisms, proteins, DNA, biomolecules and other biological media can be positioned at specific locations or sites on the plate for the purpose of performing addressable analyses on the samples. Furthermore, some or all of the sites are preferably built from a removable material in the form of micro-pallets so that a subset of the samples of interest can be readily isolated from the plate for further processing or analysis. The plate can contain structures or chemical treatments that enhance or promote the attachment and/or function of the samples, and that promote or assist in the analyses of the samples. The plate can also contain structures that aid in the coupling between the plate and external instruments or that aid in accessory operations, such as maintaining proper chemical conditions for the samples.

Further, objects and advantages of the invention will become apparent from the following detailed description.

### BRIEF DESCRIPTION OF THE DRAWINGS

FIG. 1A is a micro-patterned plate having an array of micro-pallets.

FIG. 1B is a side view of a micro-patterned plate with samples (cells) attached to pallets at specific addressable sites.

FIG. 2 is a side view of another embodiment of a micro-patterned plate and illustrates a positive selection of a sample by releasing the pallet containing the sample from the plate.

FIG. 3 is a side view of another embodiment of a micro-patterned plate with samples (organisms) attached to specific addressable sites.

FIG. 4 is a side view of another embodiment of a micro-patterned plate with samples (cells) attached to specific addressable sites.

FIG. 5 is a side view of another embodiment of a micro-patterned plate placed at the bottom of a single well of a multiwell plate, allowing conventional tools to be used with the plate.

FIG. 6 is a side view of a plate showing the use of temporary or permanent dividers to allow samples of different types or histories to be plated on the plate at different locations or within different channels.

FIGS. 7A and 7B show steps in a process using a pallet plate for adherent cell screening and culturing.

FIGS. 8A and 8B show steps in a process using a pallet plate for DNA screening.

FIG. 9 is a perspective view of an integrated pallet plate cassette for automated assays.

FIGS. 10A through M show steps in a process using an integrated pallet plate cassette for sample screening and culturing.

FIG. 11 is a schematic of a high content screening and cell selection system utilizing a micro-pallet cassette comprising an array of micro-pallets.

FIG. 12 is a schematic of a method of manufacturing micropallets by lithography.

FIG. 13 is a schematic of a method of manufacturing micropallets by patterned erosion or etching.

FIG. 14 is a schematic of a method of manufacturing micropallets by laser cutting.

FIG. 15 is a schematic of a method of manufacturing micropallets by micro-machining.

FIG. 16 is a schematic of a method of manufacturing micropallets by stenciling.

FIG. 17 is a schematic of a method of manufacturing micropallets by a transfer process.

FIG. 18 is a schematic of a method of treating micropallets surfaces to produce custom chemical properties.

FIG. 19 is a schematic of a method of treating micropallets making the micropallets surfaces biocompatible.

FIG. 20 is a schematic of a method of treating micropallets making the micropallets surfaces bioactive.

FIG. 21 is a schematic of a method of treating micropallets making the micropallets surfaces optically compatible.

FIG. 22 is a schematic of a micropallet plate integrated with a cassette.

FIG. 23 is a schematic of an array of micropallet plates integrated with a multiwell cassette.

FIGS. 24A, C and D are images of a high density micropatterened plate with releaseable micropallets during the process of releasing a micropallet.

FIG. 24B is a schematic of the process of releasing a micropallet.

FIG. 25A-D are images of cell growth on a pallet and release of the pallet.

FIG. 26 A is a schematic of a micro-pallet plate with trapped air.

FIG. 26 B is a graph comparing the threshold energy needed to release pallets with and without virtual walls of trapped air surrounding the pallets.

FIGS. 26 C-D are images of micropallet array with trapped air between micropallets and the release of micropallets.

FIGS. 27 A-F are images of micropallet array with trapped air between micropallets and the release of micropallets.

FIGS. 28 A-B are images of multi-well collection plates.

FIGS. 28 C-E are schematics of a multi-well collection plate coupled to a micropallet array plate, and the release and collection of a pallet.

FIGS. 29 A is a schematic of a method of forming micropallets with identification numbers formed in their surfaces.

FIGS. 29 B-D are images of micropallet arrays with identification numbers on each micropallet.

### DETAILED DESCRIPTION OF THE PREFERRED EMBODIMENT

Each of the additional features and teachings disclosed below can be utilized separately or in conjunction with other features and teachings to provide an improved micropatterned plate with micro-pallets that facilitates addressable biochemical analysis and improved methods for cell sorting and selection. Representative examples of the present invention, which examples utilize many of these additional features and teachings both separately and in combination, will now be described in further detail with reference to the attached drawings. This detailed description is merely intended to teach a person of skill in the art further details for practicing preferred aspects of the present teachings and is not intended to limit the scope of the invention. Therefore, combinations of features and steps disclosed in the following detail description can not be necessary to practice the invention in the broadest sense, and are instead taught merely to particularly describe representative examples of the present teachings.

Moreover, the various features of the representative examples and the dependent claims can be combined in ways that are not specifically and explicitly enumerated in order to provide additional useful embodiments of the present teachings. In addition, it is expressly noted that all features disclosed in the description and/or the claims are intended to be disclosed separately and independently from each other for the purpose of original disclosure, as well as for the purpose of restricting the claimed subject matter independent of the compositions of the features in the embodiments and/or the claims. It is also expressly noted that all value ranges or indications of groups of entities disclose every possible intermediate value or intermediate entity for the purpose of original disclosure, as well as for the purpose of restricting the claimed subject matter.

In a preferred embodiment, a system provides a micro-patterned plate comprising an addressable array of removable regions or sites to which samples can be attached. Optical encoders, electrodes, and the like enable the micro-patterned plate to be readily coupled to external instrumentation, enabling high speed addressable cell assays. Machines can move the plate to position any addressable site under the microscope. High magnification objectives can be used for imaging since only a single site is imaged (as opposed to a large field of many cells). For cells this indexing of cell positions enables much faster analysis than is currently available.

The system can be used with samples of single or multiple cells, molecules, compounds, organisms and biological and chemical media that adhere to the surfaces, as well as for samples that do not. Cavities or other entrapment devices can be used to position non-adherent samples.

The micro-patterned plate system advantageously solves the problem of positive selection of samples. The addressable array of removable pallets allows one to quickly and selectively remove samples from the plate for further processing. The use of removable pallets eliminates the need to cut around the sample, greatly increasing the speed and throughput while reducing the complexity for selecting samples. Since the pallets are arranged on a plate, high speed analysis and sample selection can be performed at rates comparable to flow cytometry in a far simpler manner.

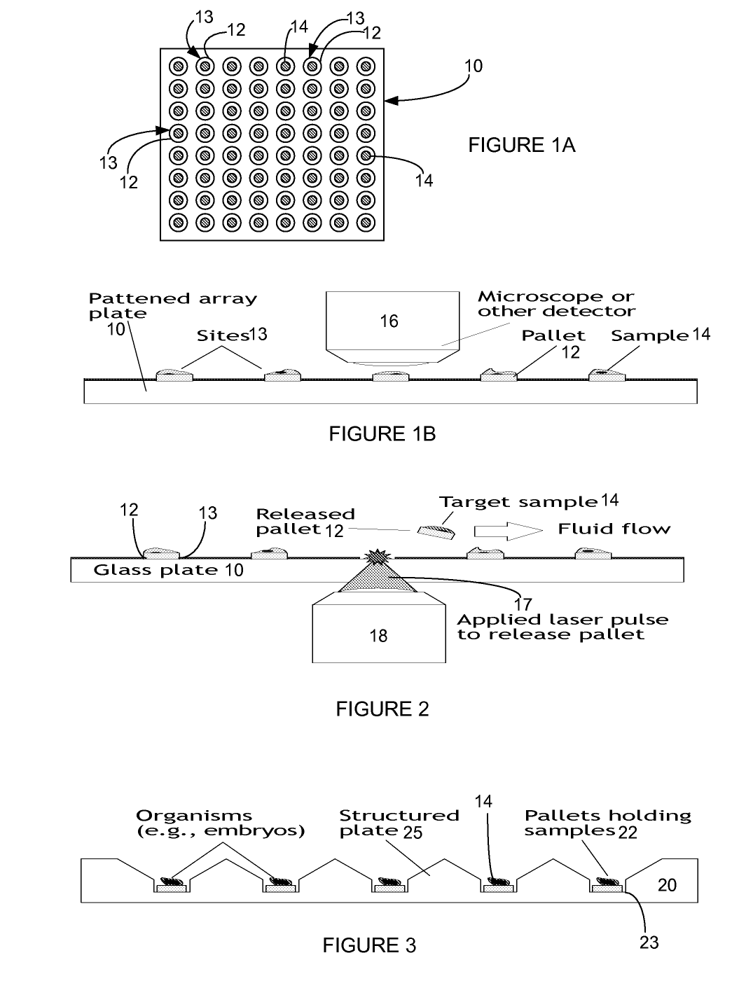

In a preferred embodiment, as depicted in FIG. 1A, a plate 10 is manufactured in such a way that samples 14 such as single or multiple cells, micro-organisms, proteins, DNA, biomolecules and other biological media can be positioned at specific locations or sites 13 on the plate 10 for the purpose of performing addressable analyses on the samples 14. Some or all of the sites 13 are preferably built from a removable material in the form of pallets 12 so that a subset of the samples 14 of interest can be readily separated and isolated from the plate 10 for further processing or analysis. The plate can contain structures or chemical treatments that enhance or promote the attachment and/or function of the samples 14, and that promote or assist in their analyses. The plate 10 can also contain structures that aid in the coupling between the plate 10 and external instruments. The plate 10 can also contain additional structures that aid in accessory operations, such as maintaining proper chemical conditions for the samples.

Referring to FIG. 1B, the micro-patterned plate 10, as depicted, includes samples 14 (such as single or multiple cells) attached to specific addressable sites 13, i.e., small, thin pallets 12 which adhere to the plate 10 at the sites 13. As depicted in this embodiment, a microscope or other detector 16 is used to image the samples 14 as the samples 14 are rapidly moved into position under the detector 16. Each site 13 can be imaged, or probed with light or other energy (e.g., magnetic, electrical, mechanical, thermal energy) to determine the properties of the samples 14 trapped at the site 13 or to modify the sample 14 at the site 13. Furthermore, the sites 13, actually pallets 12, containing samples 14 of interest can then be removed from the plate 10 for isolation from the plate 10 for further analysis or processing.

The pallets 12 are prepared on the surface of the plate 10 and preferably constructed from a second material having properties that differ from the bulk material of the plate 10. The pallets 12 can be removed from the supporting plate 10, carrying the sample 14 with it, by a variety of mechanisms so that samples 14 can be isolated and removed from the plate 10. The sites 13 or pallets 12 can be prepared by locally modifying the surface chemistry or by physically altering the surface. The sites 13 or pallets 12 are intended to be small enough to enable the entrapment of a few or single cells, micro-organisms, biomolecules or other biological or chemical media (herein called samples 14) at each site 13. The pallets 12 can also contain structures that assist in the movement or placement of the pallets 12 after removal from the plate 10.

A pallet 12 can be removed by any means appropriate. Example methods include mechanically pushing or lifting the pallet 12 from the plate 10, using localized heat or light to change the adhesion property of the pallet 12, using acoustical or mechanical shock to dislodge the pallet 12 from the plate 10, using high energy laser pulses to dislodge the pallet 12 from the plate 10, changing the electrical or magnetic properties of the pallet 12, and the like.

Turning to FIG. 2, an example of pallet removal using a laser pulse 17 from a laser 18 is shown. As illustrated, a positive selection of a sample 14 is accomplished by releasing the pallet 12 containing the sample 14 from the plate 10. As noted above, other methods of pallet release can be employed including the application of mechanical, electrical, thermal, optical, magnetic energy. The released pallet 12 can be flowed downstream for collection, or can be collected by other means (such as decanting or pipetting).

The sites 13 or pallets 12 are preferably formed close together so that the plate 10 can be moved under an analysis instrument to rapidly perform analysis of many sites 13. For example, if the sites 13 are positioned 0.1 mm apart, then the plate 10 can be moved at 50 mm/sec to analyze 500 samples per second. Samples 14 can be attached to the sites 13 in any of a number of methods. For example, living cells can be allowed to float in a medium until they attach to the sites. The remaining cells can be washed away leaving an addressable array of cells that can be rapidly imaged. Conventional methods such as spotting, silkscreening, stenciling, lithography, optical manipulation, or mechanical attachment can also be used to attach the samples to the sites.

The sites 13 or pallets 12 can form rectangular or other regular patterns (e.g., hexagonal, circular, linear, etc.), or can be randomly oriented. The patterned sites or pallets can be positioned within a larger structure such as at the bottom of a multi-well plate. The patterned plate can allow other structures to be placed within it to facilitate other functions, for example the use of temporary dividers that allow different samples to be introduced into different regions of the plate, or fluidic structures (e.g., channels) to facilitate the flow of buffer across the sites (as illustrated in FIG. 6).

Referring to FIG. 3, a micro-patterned plate 20 is shown with samples 24 (organisms) attached to specific addressable sites 23. In this embodiment, a 3-D structured pattern 25 on the plate 20 assists in the collection of the sample 24 at the specific sites, where they can be attached directly to the plate 20 or to small pallets 22 at each site 23.

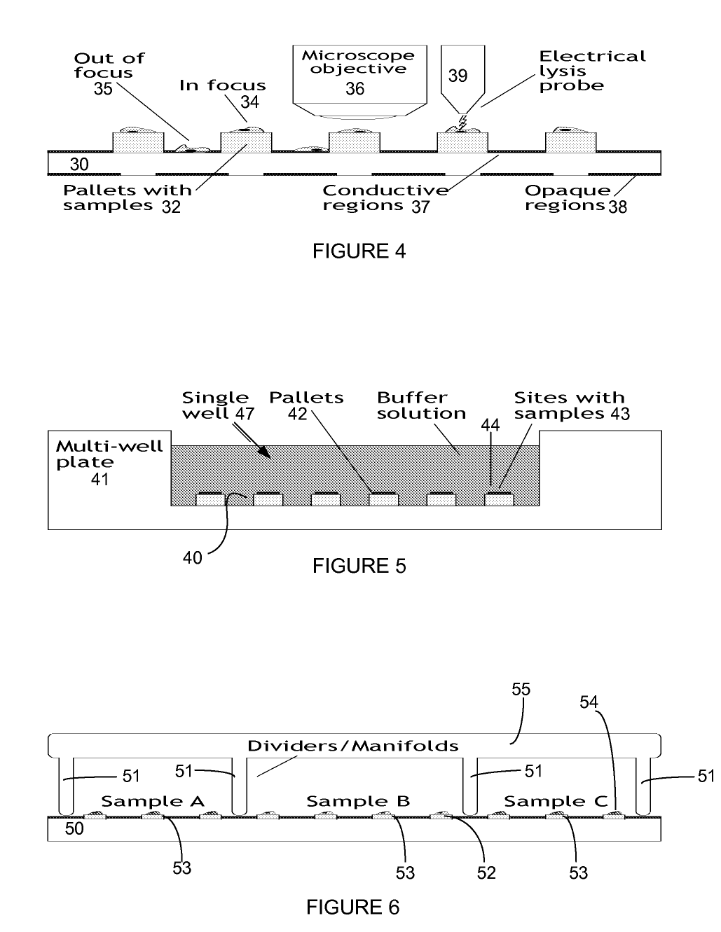

The physical shape of the surface can be modified to enhance the capture at sites (and not at non-sites), or to improve the analysis. For example, the sites (see 32, FIG. 4) can be formed on top of posts. This provides the advantage that non-sites are out of focus (see 35, FIG. 4) for a microscopy imaging system, reducing background in the image. Other examples can include cavities that trap samples within them, or opaque regions on the plate.

Other features can be added to the plate to facilitate its coupling to an external instrument. For example, optical encoders, electrodes, or magnetic devices can be included on the plate to facilitate placement; sensors can be used to test for growth conditions; fiducial marks can be included for optical alignment; etc.

Some of the noted enhancements are shown in FIG. 4. As depicted in FIG. 4. a micro-patterned plate 30 includes samples (cells) 34 attached to pallets 32 or posts at specific addressable sites. In this embodiment, a microscope objective 36 is used to image the “in focus” samples 34 as they are rapidly moved into position under the objective 36. Other included features include patterned electrodes 37, patterned opaque regions 38, and externally applied electrical fields 39 that can be used to lyse specific cells of interest.

The chemical property of the sites can also be modified to enhance the capture at the sites (and not at non-sites), or to improve the analysis. For example, surface chemistry can be modified to make some regions hydrophobic and other hydrophilic to enhance cell adhesion at the hydrophobic sites. Surface chemistry can also be used to make a non-site of the plate opaque and site-regions transparent to provide local apertures for enhanced optical imaging.

The array of sites can be produced within existing industry standard trays and cassettes. For example, the sites can be fabricated within the bottoms of multi-well plates, providing high speed addressable assays to industry standard equipment (see, e.g., FIG. 5). The array of sites can also be produced within a customized system of cartridges (see, e.g., FIG. 6).

As depicted in FIG. 5, a micro-patterned plate 40 is placed at the bottom of a single well 47 of a multiwell plate 41, allowing conventional tools to be used with the plate 40. The micropatterned plate 40 includes a plurality of pallets 42 forming a plurality of sites 43 with samples 44. A buffer solution fills the single well.

As depicted in FIG. 6, a micro-patterned plate 50 is shown to include temporary or permanent dividers 51 attached to a fluidic cap 55 to allow samples 54 of different types or histories to be plated on the plate 50 at different locations. This allows multiplexed analysis to be done on a single plate. The dividing structures 51 can also facilitate the flow of buffers over the sample regions for extraction of released pallets 52.

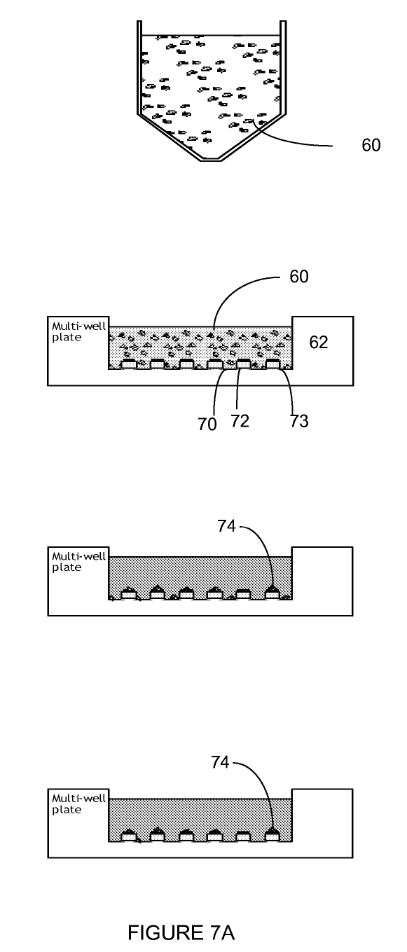

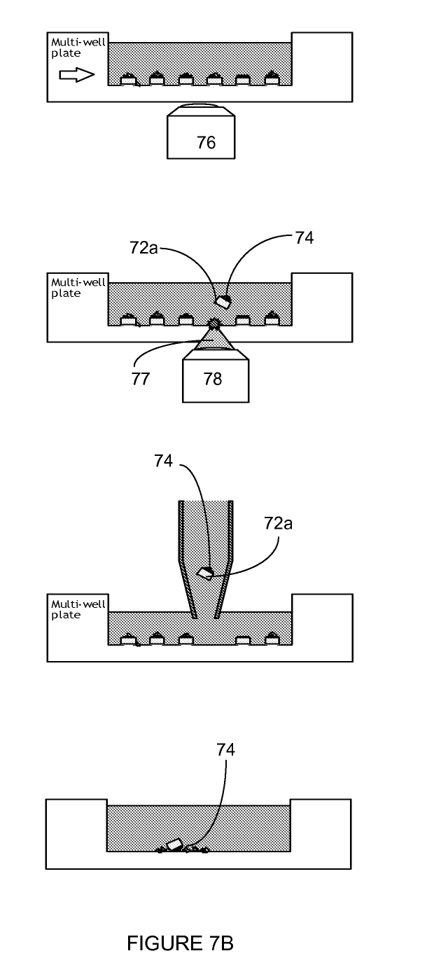

Turning to FIGS. 7A and 7B, steps in a process using a pallet plate for adherent cell screening and culturing are shown. This example illustrates how the disclosed system can be used to screen for rare cells or cells of interest from a large collection of cells. For example, the adherent cells can be taken from a patient biopsy and the disclosed system can be used to search for and select cells that show unusual or malignant behavior. Or adherent cells might be treated with a DNA vector in hopes of transfecting the cells, and the system used to find and isolate the cells that were properly transfected.

In accordance with the example process, cells 60 are pretreated, at step 1, according to an appropriate protocol, the cells 60 are then dispersed, at step 2, over the plate 70 and allowed to attach to the plate 70 or the pallet 72 at a plurality of sites 73. This can be done in a multi-well plate 62, as shown, or a single well plate. The cells adhere, as a sample 74, at step 3, to the plate 70 or pallet 72. Since the plate is treated and patterned, cells prefer to adhere at specific sites. At step 4, the plate is then preferably washed and further assay work is preferably performed to label the cells of interest. The plate is screened by detector 76, at step 5, to gain statistical information about the cell population and to identify cells of interest. Pallets 72a containing the cells of interest are (sample 74) dislodged (released), at step 6, from the plate, preferably, e.g., by a high energy laser pulse 77 from a laser 78. The free floating pallets 72a are then collected, at step 7, from the buffer solution. At step 8, new cell cultures are grown from the released cells 74.

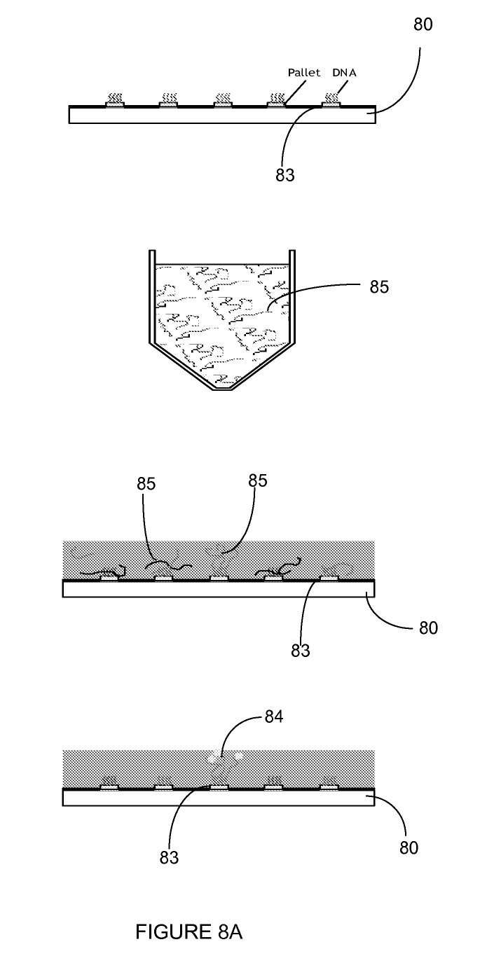

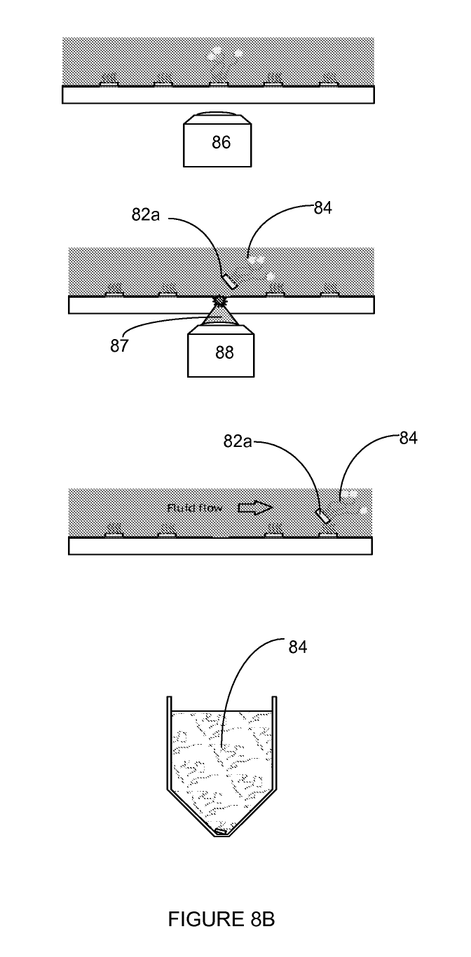

Turning now to FIGS. 8A and 8B, steps in a process using a pallet plate for DNA screening are shown. This example illustrates how the disclosed system can be used to screen for rare DNA strands from a large collection of DNA. For example, an unknown disease causing agent can be screened against a DNA plate to select strands of interest. Then the strands of interest can be isolated and PCR performed to amplify them for further analysis. The steps of the process are as follows: At step 1, a plate 80 is spotted with oligonucleotides at specific sites 83 which act as targets for DNA strands. The oligos are also prepared to act as controls.

At step 2, DNA 85 is taken from sample, denatured and pretreated according to an appropriate protocol. At step 3, DNA 85 is dispersed over the plate 80 and allowed to hybridize to their matching targets at specific sites 83. At step 4, the plate is thoroughly washed to remove unbound DNA. Further assay work is performed to label the DNA of interest. The plate is then screened by the detector 86, at step 5, for statistical analysis of the sample and to identify DNA of interest. The pallets 82a containing the DNA of interest 84 are dislodged (released), at step 6, from the plate 80 by a high energy laser pulse 87 from a laser 88. At step 7, the free floating pallets are collected from the buffer solution. At step 8, DNA 84 is denatured from the pallet and used in PCR reaction to amplify the sample.

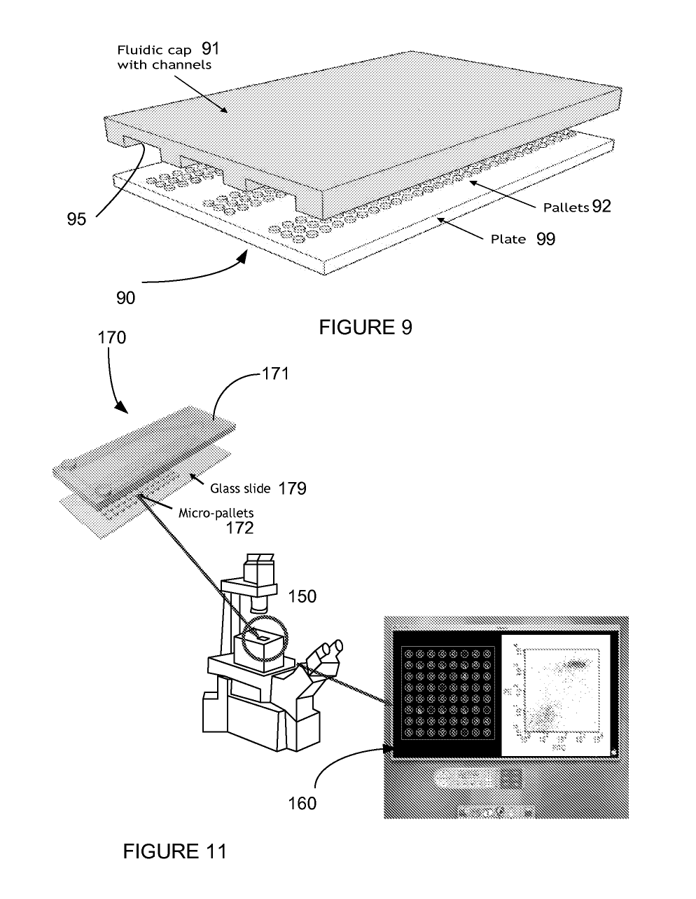

Referring to FIG. 9, an integrated pallet plate cassette 90 for automated assays is illustrated. This example illustrates how the disclosed system can be integrated into other systems to produce an automated cartridge system. As depicted in FIG. 9, the integrated pallet plate cassette 90 includes a micropallet plate 99 with a plurality of pallets 92 formed in three arrays on the plate 99, and a fluidic cap 91 with small channels 95 formed on its underside. The cap 91 mates with the micropallet plate 99 to flow buffers over the pallets 92.

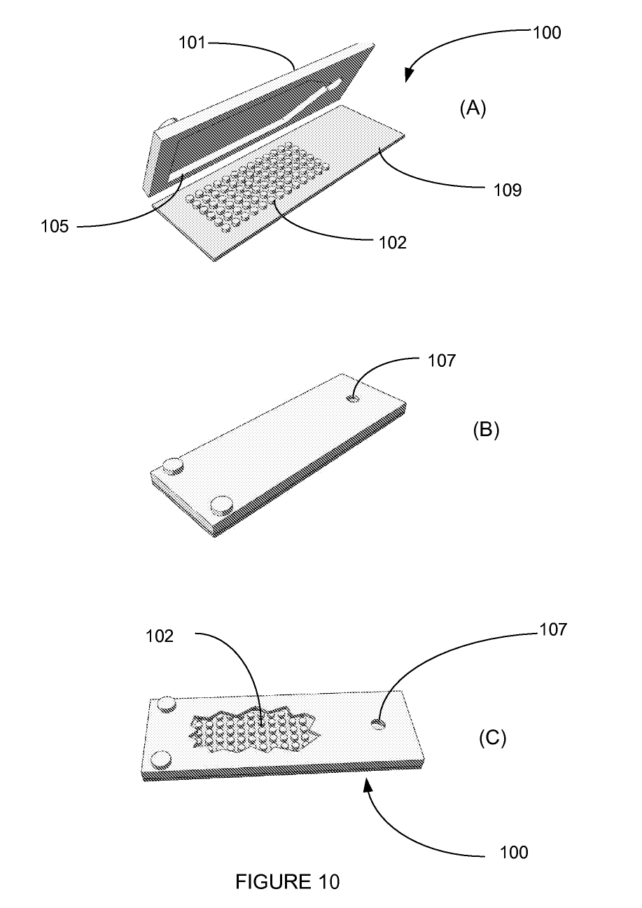

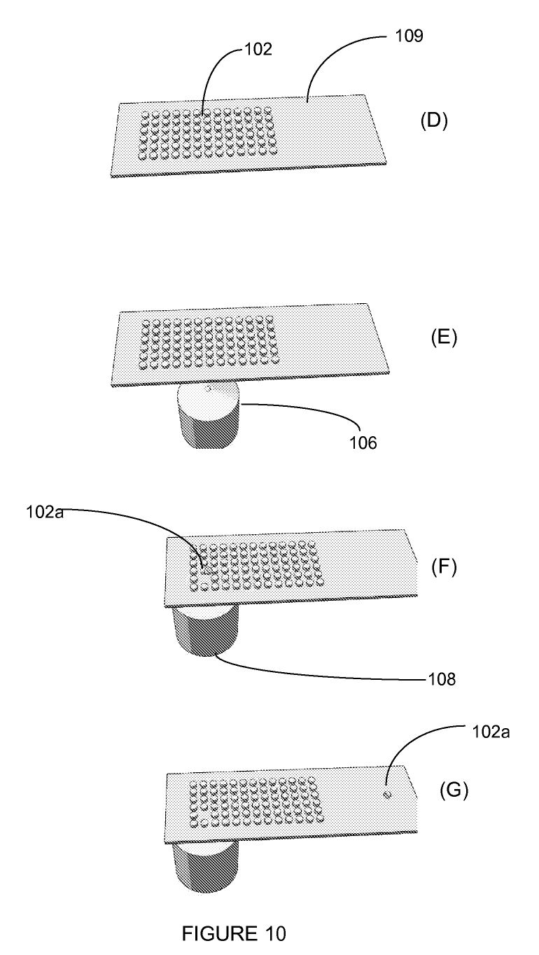

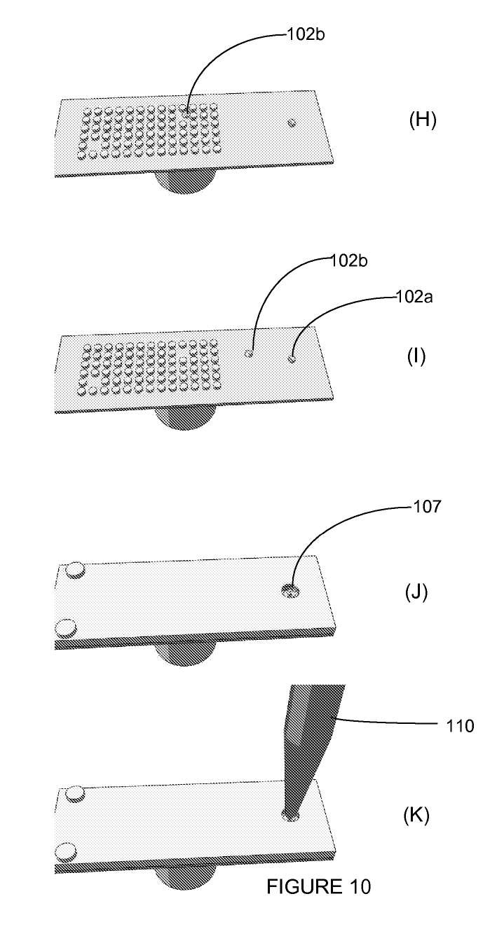

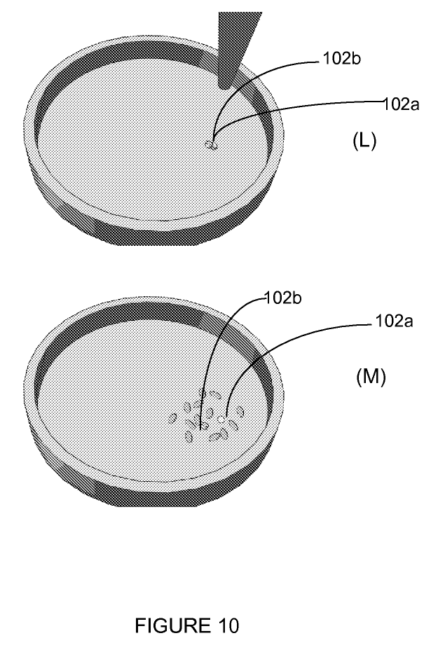

Turning to FIGS. 10A through M, a process using a micro-machined integrated pallet plate cassette 100 is shown. The cassette 100 includes a pallet plate 109 that preferably includes a pre-set array of releasable pallets 102 for cell culturing that are releasably positioned atop of the plate 109 formed of glass or the like. The pallets 102 are preferably treated to promote cell growth at the center of the pallets 102. The pallets 102 are preferably indexed, e.g., bar coded, so that their positions are known in advance of use of the cassette 100.

In FIGS. 10 B and 10C, the cap 101 is closed on to the plate 109 revealing an access hole 107. In FIG. 10D cells are dispersed over the plate 109 and allowed to attach to the plate at specific sites 102 or pallets. The plate 109 is then screened by the detector 106, as depicted in FIG. 10E, for statistical analysis of the sample and to identify cells of interest. A pallet 102a containing the cells of interest is dislodged (released), as shown in FIG. 10F, from the plate 109 by a high energy laser pulse from a laser 108. As shown in FIG. 10G, the free floating pallet 102a is collected from the buffer solution toward the end of the plate 109. In FIG. 10 H, a second pallet 102b containing additional cells of interest is dislodged (released) from the plate 109 by a high energy laser pulse from a laser 108. As shown in FIG. 10I, the free floating pallet 102b is collected from the buffer solution toward the end of the plate 109. As depicted in FIGS. 10J and 10K, the pallets 102a and 102b are extracted through access hole 107 using an extractor 110. New cell cultures are grown from the released cells, as shown in FIGS. 10L and 10M.

As shown in FIG. 1, a cassette 170 comprising a substrate or plate 179 formed of glass or the like and a cap 171. The plate 169 can include an array of micro-pallets 172—e.g., providing 500,000 (50×50 microns) pallet sites—positioned on the plate 179. The cassette 170 can be used with a microscope attachment 150 for imaging, fluorescent analysis, sorting, and the like. Analysis software provided on a computer 160 can be used for high content screening and cell selection. A pallet extractor can be used to extract a selected pallet from the cassette 170.

The micro-pallet array system described herein advantageously enables the analysis of cells or other materials residing on the pallets for a variety of properties, followed by positive selection of cells while the cells remain adherent to the pallets. The pallet release and collection process of the micro-pallet array system subjects the cells to less perturbation than sorting by flow cytometry, since the cells remain adherent during both analysis and sorting. Improved cell health and viability is provided as a result. Moreover, cells grown on the pallets will display their full set of cell-surface proteins as well as retain their native morphology and signaling properties. Thus, a broader set of cell attributes are available for use as selection criteria. Importantly, these properties can be analyzed over time to enable selection based on the temporal change of a particular property.

Improved methods for manufacturing a plate with releasable micropallets are provided below. Also provided are methods for manufacturing a cassette that contains the plate of releasable micropallets.

A method of manufacture of a plate of polymer pallets using optical lithography and photosensitive polymer: A plate is prepared from glass, plastic or other suitable material. This plate is cleaned using standard cleaning procedures. Optionally, this plate may have a thin layer of adhesion promoter applied, such as siloxane or similar chemical known to change the adhesion properties of a surface.

A photosensitive polymer is coated on this plate by any of a variety of means, including spinning, dipping, coating, spraying, etc. This polymer contains a photosensitive chemical that will change the chemical property of the polymer upon exposure to light. The polymer coating is allowed to settle and is dried, if necessary. Some photosensitive polymers may be used in wet state. Physical modifications to the surface of the dried polymer may be made, including roughening, polishing, embossing, divoting, etc.

A mask with appropriate opaque and transparent patterns representing the desired releasable elements is prepared in advance. This mask is placed in the path of a beam of light which is used to expose the polymer to light in specific regions only. The polymer is exposed to light using this mask causing it to change its chemical structure. After the exposure process is complete, parts of the polymer are washed away using an appropriate solvent, leaving the photopatterned polymer on the plate.

This process may be repeated multiple times using one of more materials to generate interesting pallet shapes, including 3-D structures. Those skilled in the art will recognize variations on this method to produce pallets of various shapes and texture.

Further treatments may be applied to make the plate more useful for its intended applications. Hydrophobic or hydrophilic coatings may be applied using aqueous, solvent or vapor phase treatments. Further, plasma-based treatments, radiation treatments, physical treatments, thermal treatments, photonic treatments, etc. may all be applied to modify the surface as desired.

The plate with patterned polymer pallets may be cut to create a new shape, or to produce many smaller plates containing pallets.

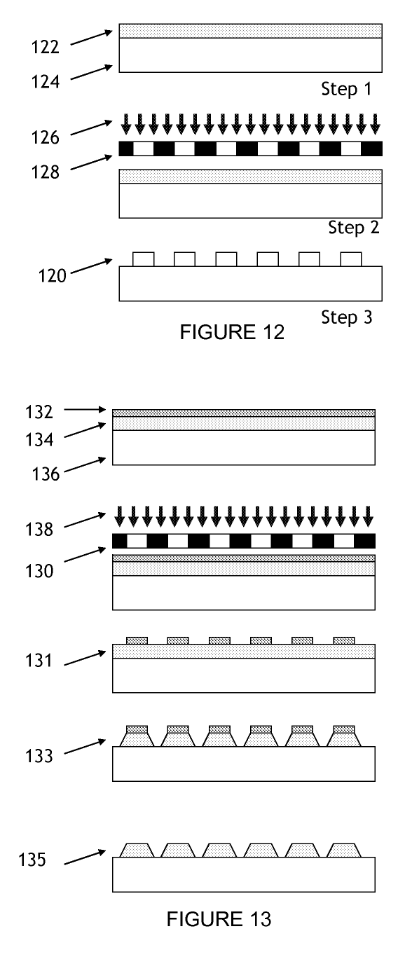

An example of a method manufacturing micropallets by lithographic means is illustrated in FIG. 12. A photosensitive polymer 122 is prepared (Step 1) on the surface of a plate 124. Light 126 is directed (Step 2) through a mask 128 to expose the polymer at certain regions. The polymer is developed, leaving (Step 3) micropallets 120 that are solid.

A method of manufacture of a plate of pallets by optical lithography and etching: A plate is prepared from glass, plastic or other suitable material. This plate is cleaned using standard cleaning procedures. Optionally, this plate may have a thin layer of adhesion promoter applied, such as siloxane or similar chemical known to change the adhesion properties of a surface.

A thin material layer, made from any of a plurality of materials including glass, plastic, metal, ceramic, with thickness typically ranging from 0.01 mm to 1 mm is formed on the surface of the plate. One method for forming the thin material layer is by laminating a thin material on the glass using an adhesive. If the laminate is glass, the glass may be any of many standard glasses, including silicate, quartz, borosilicate, soda lime, etc. In addition, the laminate may be a glass of the UV sensitive variety, such as “Borofloat®” which changes its etch resistance after exposure to UV light.

Alternatively, the thin material layer my be applied by casting, spinning, spraying, dipping, painting, molding etc. if it can be first applied in a liquid form, such as for example polymers dissolved in solvents or polymers intended to be crosslinked by reaction (e.g., epoxies, polyurethanes).

Alternatively, the thin material layer may be applied to the plate by first melting the material, then forming it over the surface of the plate, for example injection molding.

Alternatively, the thin material layer may be applied to the plate by growing it on the surface of the plate, such as by polymerization or by electroplating.

Alternatively, the thin material layer may be applied to the plate by depositing it on the surface of the plate, such as by physical vapor deposition, chemical vapor deposition, or chemical precipitation.

After creation, the thin material layer may be further treated to chemically or physically change the surface. Treatments may include application of chemicals, etching, polishing, roughening, etc.

A photoresist layer is coated over the laminate to form a protective surface using standard methods such as spinning, spraying, etc. This photoresist is patterned using standard optical lithography techniques to open up spaces in the photoresist that expose the laminate. If desired, metal may be coated under or over the photoresist to form a “hard mask” that has greater protective properties than the photoresist. This metal may be patterned in any of the standard methods known in the art of microfabrication. These patterned materials are referred to as the protective layer.

The laminate is etched using the patterned photoresist or metal to protect pallet regions. The etching may be performed using a chemical known to etch the material, such as hydrofluoric acid for glass, potassium hydroxide for silicon, ferrous chloride for copper, etc.

Alternatively, the material may be etched using dry etch techniques such as reactive ion etching chemistries using plasmas.

Alternatively, the material may be etched using physical erosion techniques such as micro sandblasting.

Once the pallets have been etched from the thin material layer, the protective layer is stripped using solvent or appropriate chemistry.

This process may be repeated multiple times to generate interesting pallet shapes, including 3-D structures. Those skilled in the art will recognize variations on this method to produce pallets of various shapes and texture.

Further treatments may be applied to make the plate more useful for its intended applications. Hydrophobic or hydrophilic coatings may be applied using aqueous, solvent or vapor phase treatments. Further, plasma-based treatments, radiation treatments, physical treatments, thermal treatments, photonic treatments, etc. may all be applied to modify the surface as desired.

The plate with patterned pallets may be cut to create a new shape, or to produce many smaller plates containing pallets.

Turning to FIG. 13, a method of manufacturing micropallets by patterned erosion or etching is illustrated. A first material 132 such as photosensitive resist is prepared on the surface of a second material 134 such as a polymer that is intended to be the micropallet material. The second material 134 is prepared on a plate 136. Light 138 is directed through a mask 130 to expose the resist 132 at certain regions. The resist 132 is developed, leaving small protective regions 131 that are solid. The micropallet material is selectively removed using chemical or physical means 133. The resist is cleaned, leaving micropallets 135. This may also be performed using a stencil. Both etching and erosion may be used.

A method of manufacture of a plate of pallets by the use of a stencil: A plate is prepared from glass, plastic or other suitable material as described earlier. A thin material layer is formed on the surface of the plate as described earlier. The thin material layer may be further modified as described earlier.

A stencil is created from a second plate or film with openings that correspond to regions on the thin material layer that are to be removed when forming the pallets. The stencil is placed over the thin material layer to protect it from the processes that follow.

Physical erosion techniques are applied to remove material from beneath the openings in the stencil. Techniques include micro-sandblasting, water jet, laser etching, etc. After removal of unwanted material, a second stencil may be applied to the material to continue the process of removal of unwanted material. After completion, the resulting freestanding material consists of pallets.

Further treatments may be applied to the plate as described earlier. In addition, the plate may be cut into new shapes or smaller plates.

An alternative approach for the use of a stencil is to use the stencil to place protective material at specific placed over the thin material layer. This protective material can then protect the material layer from etching, ablation, or physical erosion. When completed, the protective material is stripped from the surface of the pallets.

This process may be repeated multiple times to generate interesting pallet shapes, including 3-D structures. Those skilled in the art will recognize variations on this method to produce pallets of various shapes and texture.

A method of manufacture of a plate of pallets by the use of a laser: A plate is prepared from glass, plastic or other suitable material as described earlier. A thin material layer is formed on the surface of the plate as described earlier. The thin material layer may be further modified as described earlier.

A laser is used to etch material away at undesired locations to produce pallets. The laser beam may be moved over the material to directly ablate the material. Alternatively, the laser beam may be directed through a mask or stencil to produce the pallets. The laser may be used multiple times to generate interesting shapes, patterns and textures on the pallets.

This process may be repeated multiple times to generate interesting pallet shapes, including 3-D structures. Those skilled in the art will recognize variations on this method to produce pallets of various shapes and texture.

Further treatments may be applied to the plate as described earlier. In addition, the plate may be cut into new shapes or smaller plates.

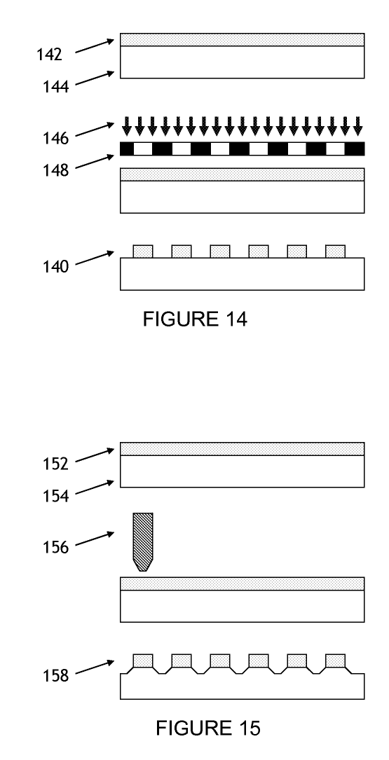

FIG. 14 provides an illustrated example of micropallets manufactured by laser cutting. As depicted, a material 142, which is intended to be the micropallet material, is prepared on the surface of a plate 144. High intensity light 146, as from a laser, is directed at the polymer. The light may pass through a mask or stencil 148. Or the laser may be moved and modulated to create an effective pattern of light on the surface. The polymer is ablated or removed as a result of the laser, leaving behind micropallets 140. This method may be combined with others (such as light assisted etching), if desired to produce meiropallets. This process may be repeated multiple times to produce desired shapes.

A method of manufacture of a plate of pallets by the use of machining a material. A plate is prepared from glass, plastic or other suitable material as described earlier. A thin material layer is formed on the surface of the plate as described earlier. The thin material layer may be further modified as described earlier.

A machine tool such as an end mill or precision saw is used to machine away selected material from the thin material layer. The resulting structures are pallets.

Further treatments may be applied to the plate as described earlier. In addition, the plate may be cut into new shapes or smaller plates.

This process may be repeated multiple times to generate interesting pallet shapes, including 3-D structures. Those skilled in the art will recognize variations on this method to produce pallets of various shapes and texture.

FIG. 15 provides an illustrated example of micropallets manufactured by machining. As depicted, a material 152, which is intended to be the micropallet material, is prepared on the surface of a plate 154. A cutting tool 156 such as a diamond saw is brought in contact with the micropallet material 152. The cutting tool 156 is used to cut openings in the micropallet material 152, resulting in free-standing micropallets 158.

A method of manufacture of a plate of pallets by the use of molding a polymer: A plate is prepared from glass, plastic or other suitable material as described earlier. Polymer material is created on the surface of the plate by any of a plurailtiy of techniques, including casting, spinning, dipping, painting, spraying, laminating, etc. The polymer layer may be modified as described above. The polymer is heated to its reflow temperature and a mold containing a relief pattern is embossed against the soft polymer. The polymer is allowed to cool and the embossing mold is removed. The resulting structures in the polymer form the initial version of the pallets. An etchant or solvent is used to remove residue between the pallets. The polymer pallets may then be annealed or re-embossed to secure them to the plate.

Alternatively, the embossing procedure may use a reaction-cure themoset polymer. In this case, the embossing plate is used to mold the polymer as it cures. After cure and removal of the plate, the method proceeds as with the thermoplastic.

This process may be repeated multiple times to generate interesting pallet shapes, including 3-D structures. Those skilled in the art will recognize variations on this method to produce pallets of various shapes and texture.

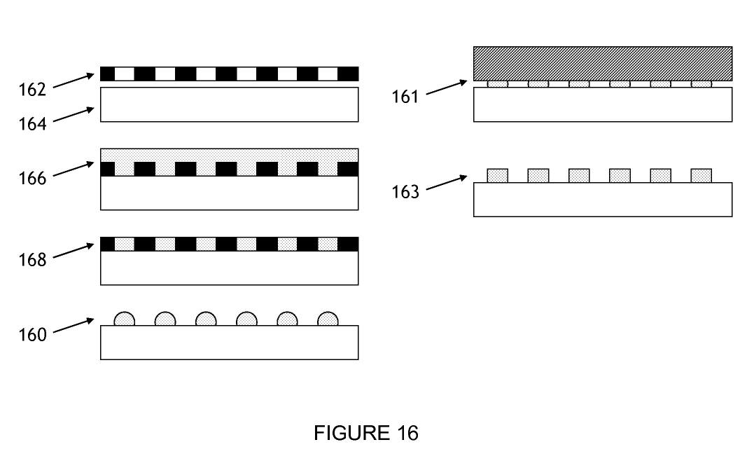

Referring to FIG. 16, an example of micropallets manufactured by stenciling is illustrated. A stencil with pre-cut openings 162 is brought in contact with a plate 164. Material 166 is forced through the stencil using a squeegee, blade, or other tool. The excess material is removed leaving the stencil and contained material 168. The stencil is then removed leaving patterned material 160. If desired, the patterned material may be further processed with heat, pressure, embossing, etc. 161 to produce micropallets 163 of the desired shape and material property.

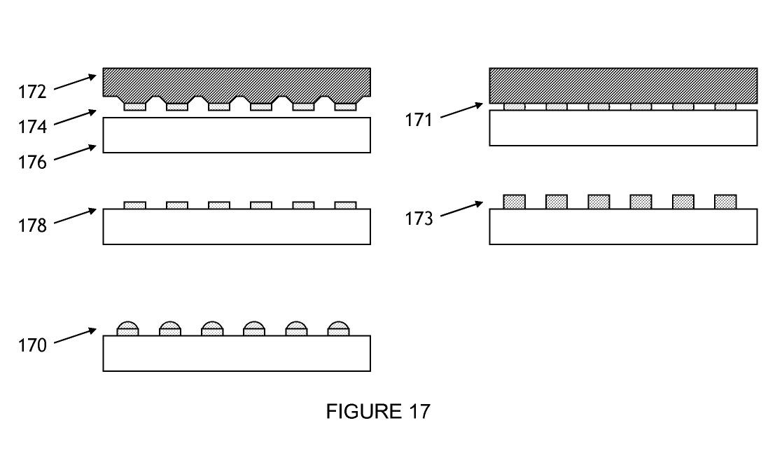

Turning to FIG. 17, an example of micropallets manufactured by a transfer process is illustrated. A stamp 172 with prefabricated geometry is prepared with chemical moieties 174 on its surface. The chemical moieties 174 are pressed against a plate 176. The chemical moieties 174 are transferred to the plate 178. The transferred chemical moieties are used as catalysts or precursers to subsequent materials growth 170. New materials may by treated with heat, embossing, etc. 171 to result in micropallets 173.

A method of manufacture of a plate of pallets by modifying pallets to produce desired surface properties: A plate is prepared from glass, plastic or other suitable material as described earlier. A material is created on the surface of the plate as described above. Prior to processing into pallets, the surface of the thin material layer may be treated to prepare it for coating processes to follow. This treatment may include the bonding of chemicals to the surface, the activation of chemistries at the surface (through the use of corona, plasmas, UV light, ions, chemical etching or oxidization, or radiation), chemical growth of materials at the surface, chemical or physical deposition of materials at the surface (such as vapor deposition, electroless plating), surface-induced grafting polymerization, or the physical adsorption of chemicals on the surface. This treatment may be intended as the final surface treatment for the pallets, or may be intended as a primer for further treatments to follow. By selecting an appropriate surface modifying method, the resulting surface modified pallet can be made to be hydrophilic, hydrophobic, biocompatible, chemically resistance, non-sticky, wettable, or combinations thereof.

After processing into pallets, the top surface of the pallets may be further treated using the primer layer. Many surface treatments only work with an appropriate primer layer, so the chemical process will only affect the top layer.

Alternatively, the tops of the pallets can be modified by applying chemicals known to change the surface property of the material pallets, but do not change the surface property of the plate material.

Alternatively, a primer may be applied to the top surface of the pallets without pre-treatment of the material prior to forming the pallets. This is performed using light, typically UV or directed radiation to activate the chemistries on the surface of the pallets. The surface of the plate may be chosen so that it is not responsive to the light or radiation. In this case, the resulting chemical treatments will apply only to the activated surface on the top of the pallets. Actual chemistries can vary significantly, depending on the material to be placed on the surface.

Alternatively, the surface modifying methods described above may be applied after pallets are processed. In this case, the surface treatments apply to both the top surface and sidewall of the pallets.

Alternatively, after processing into pallets, the surface property of the plate material can be modified by applying a chemical known to change the surface property of the plate material, but do not change the surface of the pallets materials.

The radiation or light may be passed through as stencil or mask to pattern the treatment on the pallets on the plate, or to place the surface treatment on only specific pallets on the plate.

Alternatively, the tops of the pallets can be modified by using a flat plate containing chemicals of interest and pressing it against the tops of the pallets in order to transfer the chemicals to the surfaces of the pallets.

Alternatively, the tops of the pallets can be modified by roughening them in order to promote adhesion to a material intended for the surface.

Alternatively, the pallets may be treated using machines or tools that can accurately dispense chemicals at desired locations on the plate in order to treat only certain pallets on the plate.

This process may be repeated multiple times to generate interesting patterns of surface treatments.

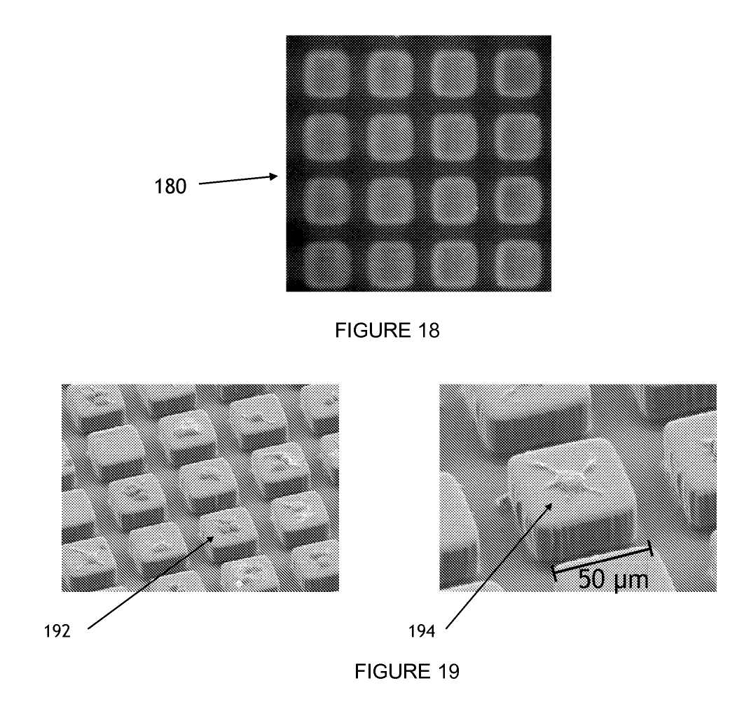

An example of treating micropallets surfaces to produce custom chemical properties is illustrated in FIG. 18. As noted above, micropallets can be treated to have new surfaces other than the native bulk material of the micropallets themselves. In this example, Epoxy-based micropallets were soaked in a polyethylene glycol solution, adsorbing it into the surface of the polymer. Following this, the polyethylene glycol treated micropallets showed no adsorption of a protein labeled with Alexa 647 labeled. As depicted in FIG. 18, the untreated micropallets 180 showed significant adsorption of protein as is seen by the fluorescent label, Alexa 647. Many different methods can be used to place chemicals or materials on the surfaces of micropallets.

Turning to FIG. 19, an example of making the micropallets surfaces biocompatible is provided. By placing certain polymers on the surface, the micropallets can be made to support the growth of biological entities such as cells. Surface modification can be accomplished in a variety of ways, including the use of multiple layers of treatment. This example shows cells growing and multiplying on micropallets 192 that have been coated with poly-D-lysine. Closeup image shows cell 194 with pseudopods extended, indicating a healthy cell with good attachment.

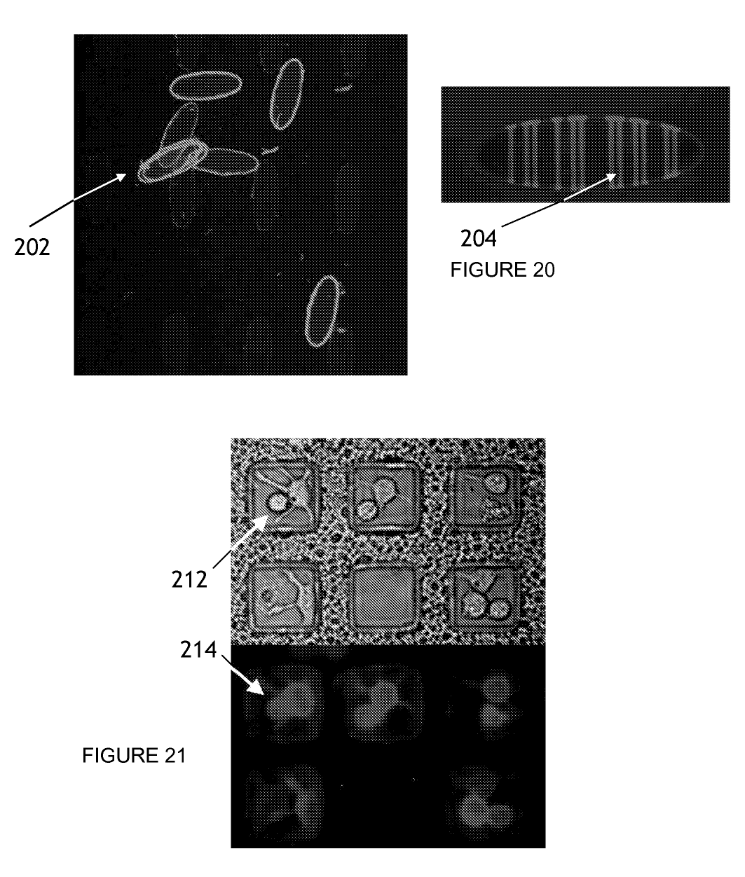

FIG. 20 provides an example of micropallets surfaces that are made bioactive. By placing certain polymers on the surface, the micropallets can be further treated to hold materials 202 such as antibodies, DNA, and other biological molecules. This image shows the materials 202 glowing due to fluorescence. These types of coatings make them useful for binding-style assays. If light is used to assist in the grafting process, then the coatings 194 may be patterned to be highly localized by grafting with light and a mask.

FIG. 21 provides an example of micropallets that are optically compatible. By adjusting the amount of photoinitiator in the micropallet, or by performing a photobleaching process after manufacturing (prolonged exposure to intense light), the micropallets can be made to be useful in both imaging 212 and fluorescent applications 214. Materials selection can be performed to optimize the micropallet for optical interrogation.

A method of manufacture to integrate a plate of pallets with a cassette or a multi-well plate: A cassette may be used to hold the plate of pallets. This cassette may be manufactured using any of a plurality of methods including injection molding, blow molding, stamping, machining, assembling, and the like. In one embodiment, the cassette is manufactured to hold fluid without leaking. The cassette is designed to contain a region where the pallet plate can be attached. The pallet plate may be bonded to the cassette by many conventional methods, including the use of adhesive.

Alternatively, the plate of pallets may be held in place in the cassette by friction or pressure. Alternatively, the plate of pallets may be held in place by magnets.

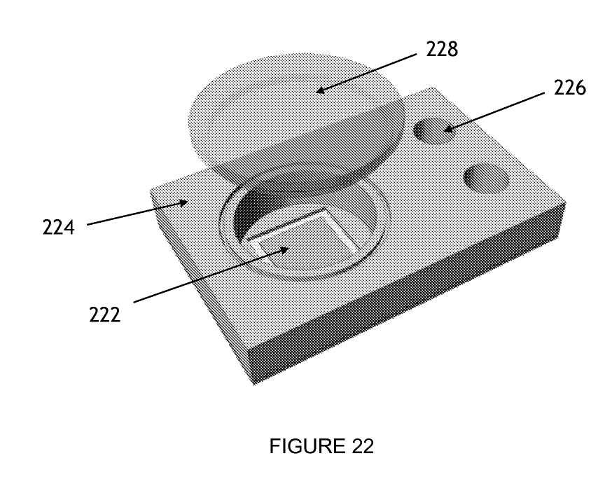

FIG. 22 illustrates an example of a micropallet plate integrated with a cassette to ease handling, store fluids, and maintain sterility. As depicted, a single cassette 224 includes micropallet arrays 222 patterned inside. A plate of micropallets 222 is attached to the bottom of a cassette 224 which is designed to house the micropallets and provide a chamber for buffer to sit during culture. Optionally, it may contain reservoirs 226, fluidic lines, and even active components, such as heaters. The cassette may contain a lid 228 to keep the buffer contained and reduce evaporation of the cell buffer.

Alternatively, the plate of pallets may be attached to a multi-well cassette such as those commonly used in the biotech industry. In this embodiment, the pallet plate is manufactured so that it is small enough to be placed within the space of a single well on a multiwell cassette. The pallet plate may be attached to this region in any manner, as indicated before. Multiple pallet plates may be attached to multiple wells. Holes may be opened in the wells of a multiwell plate in order to accommodate the pallet plate.

Alternatively, a single large plate of pallets may be used to attach to the entire bottom of a multiwell plate.

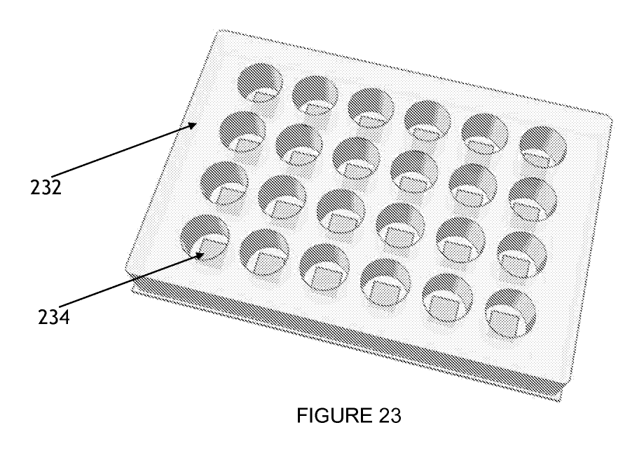

FIG. 23 illustrates an example of an array of micropallet plates integrated with a multiwell cassette for automated systems. As depicted, a 24-well array microplate cassette 232 includes micropallet arrays 234 patterned inside the wells. Micropallets arrays 234 preferably form a grid 8 mm×8 mm in dimension. This preferably will hold 6,400 pallets of 50 Mm (+100 μm pitch) or 400 pallets of 300 μm (+400 μm pitch). The bottom of plate is built from glass and is about 112 mm×76 mm. The plate dimensions are about: 14 mm diameter wells with 18 mm pitch with the outside dimensions of 127.76 mm×85.47 mm×16 mm. These dimensions are typical, but not restrictive.

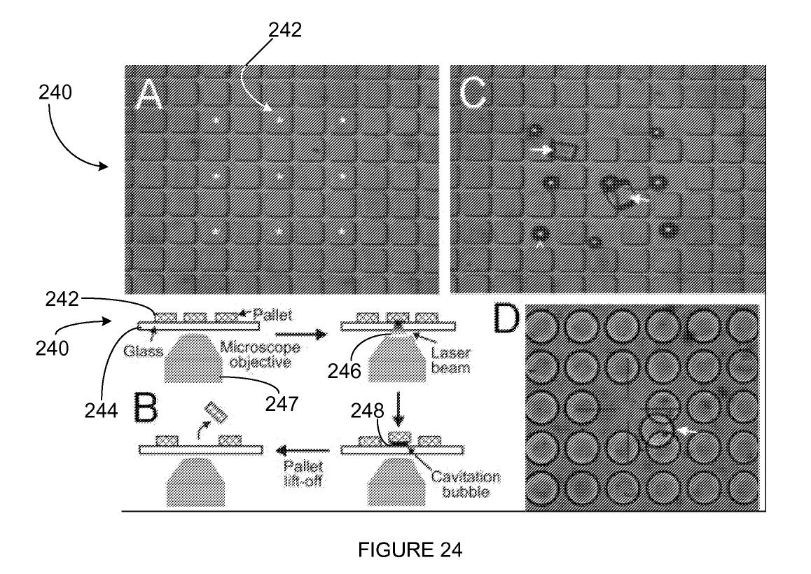

As part of an experiment, a high density micropatterned plate 240 includes an array of micropallets 241 composed of SU-8 material were fabricated on a glass surface 244 as shown in FIG. 24A. SU-8 photoresist is an epoxy-based material that becomes cross-linked upon exposure to near UV light. Use of SU-8 photoresist has become widespread through out the semiconductor industry since it can be used to fabricate microstructures with high aspect ratios and near vertical walls. An advantage of SU-8 is that it is optically transparent at most visible wavelengths. Using microfabrication methods described above, arrays of pallets with varying heights, shapes, and surface areas can be formed. Advantageously, a large numbers of the pallets can be fabricated on a conventional biologic surface such as a microscope slide. For example, 20,000 square pallets with a 50-μm side and 20-μm spacing are present in 1 cm². Thus, a single array could possess hundreds of thousands of pallets in an area of practical dimensions.

For the pallet array to be suitable for use in, for example, a cell cloning method, individual pallets located in the midst of large numbers of nearby pallets are preferably releasable on demand. Typically, when using SU-8 in combination with glass, a metal layer is placed between the SU-8 and glass surface to enhance adhesion. Without the intervening metal layer, the SU-8 preferably weakly adheres to the underlying glass. Omission of the metal layer tends to yield arrays of pallets that can be detached with a mechanical force of the appropriate magnitude.

To release a micropallet 242, a focused beam 246 of a laser (preferably passed through a microscope objective 247), as depicted in FIG. 24B, was used to generate a mechanical force localized to dimensions of micrometers. A single pulse (5-ns duration) of a Nd:YAG laser (532 nm) was focused at the interface between the glass and SU-8 pallet. When a laser beam is focused to a sufficiently small diameter, a localized plasma is created, which in turn produces an outwardly propagating shock wave and an expanding cavitation bubble 248. In an aqueous solution, up to 5% of the laser's energy can be transmitted to the cavitation bubble yielding a bubble tens of micrometers or more in diameter. To determine whether the shock wave and cavitation bubble generated by the laser-induced plasma could release a pallet, a single pulse of low energy (2-5 μJ) was focused at the SU-8 glass interface below a pallet. The pallets 242 marked with an asterisk in FIG. 24A were released without disturbing neighboring pallets as shown in FIGS. 24 C and D. Under these conditions, 100% (n>100) of targeted pallets were released and 0% of adjacent pallets were detached. The shock wave, cavitation bubble, or both yielded localized mechanical forces centered at the focal point of the laser beam and restricted to a single pallet. Multiple pallets in an array could be released by moving the microscope stage to sequentially place pallets in the path of the focused beam (see, e.g., FIGS. 24A and C). For these small pallets (50-μm side), the mechanical energy was frequently sufficient both to detach the pallet and to propel the pallet from its array site (and often from the field of view of the microscope) (see, e.g., FIGS. 24 C and D). When pallets were released, there was frequently a small defect on the face of the pallet that was in contact with the glass surface, suggesting that the plasma formed adjacent to this surface and at the interface between the SU-8 and glass surfaces.

Smaller and larger pallets could also be released using the focused laser pulse. Pallets with a 30-μm side were released at lower energies (<2 μJ) with 100% efficiency and 0% cross talk (release of adjacent pallets). Larger pallets (>100 μm) required higher energies to effect a 100% release rate. For example, square pallets with a 250-μm width required 6 μJ of energy. Even at these higher energies, no adjacent pallets were released. Multiple laser pulses could be used to release pallets at energies lower than a single pulse (data not shown). A variety of other pallet shapes (ovals and hexagons) and sizes (20-250 μm) were also successfully released with this laser-based method.

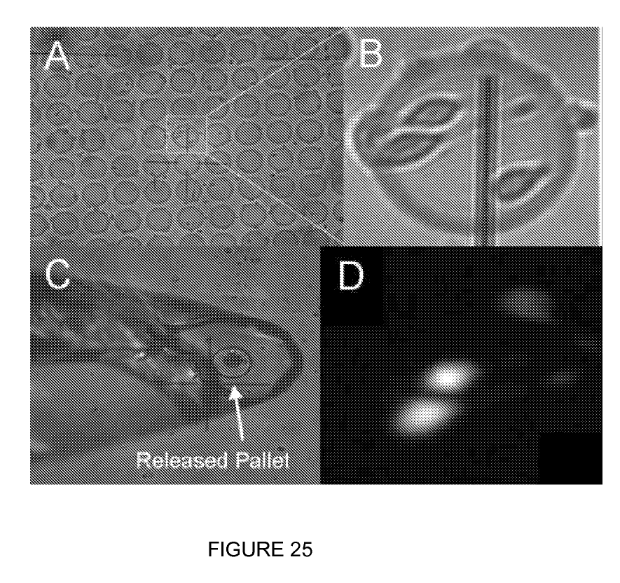

In previous studies, SU-8 was found to be biologically compatible. However, cells do not adhere well to the surface of native SU-8. SU-8 slabs incubated with fibronectin or collagen did support attachment and growth of RBL, 3T3, and HeLa cells (data not shown). Pallet arrays were incubated with fibronectin or collagen followed by culture of 3T3, RBL, or HeLa cells on the array. While most cells did not attach to the top surface of the pallets, some pallets did possess cells on their top surfaces as shown in FIGS. 25 A and B. To determine the feasibility of releasing pallets with living cells, the pallets with cells on their surface were released using the focused beam of the laser as shown in FIG. 25C. Prior to release, the cells were loaded with a viability indicator, Oregon Green diacetate. Most cells on the top surface of the pallet retained the Oregon Green, suggesting that the plasma membrane was intact and that the cells were living (see FIG. 25D). In contrast, cells adherent to the sides of the pallets frequently did not retain the indicator, suggesting that they were often killed by the release process.

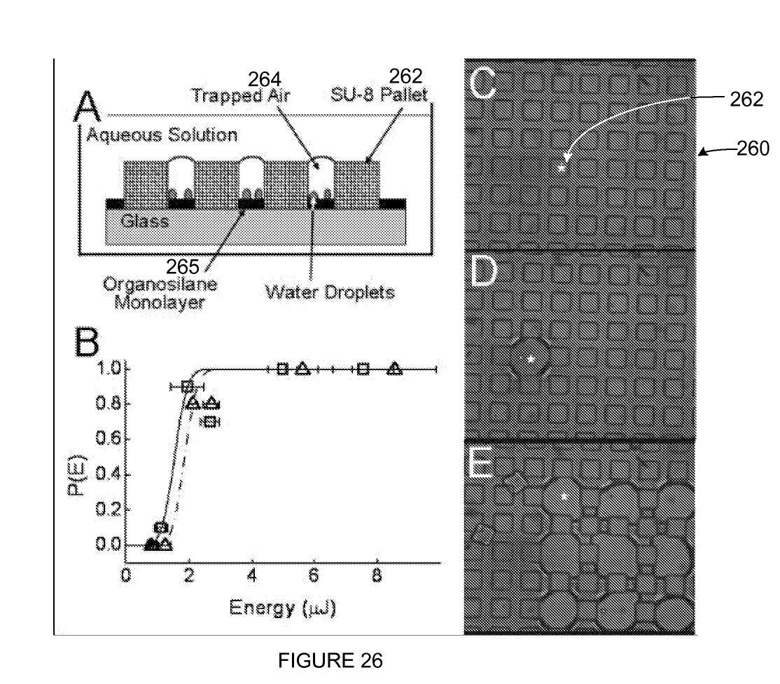

To decrease the accessibility of cells to the pallet side walls, virtual walls of air were created between the SU-8 pallets. As discussed in U.S. patent application Ser. No. 11/539,695, filed Oct. 9, 2006, which is incorporated herein by reference, hydrophobic coatings 265 placed on a glass surface between SU-8 structures 262 could be used to trap air 264 as depicted in FIG. 26A. The air trapped 264 between the microstructures 262 was stable for many weeks and excluded cells and molecules from the regions between the SU-8 structures 262.

To determine whether SU-8 pallets surrounded by trapped air could be released by the focused laser, an array of micropallets 260 was coated with (heptadecafluoro-1,1,2,2-tetrahydrodecyl)trichlorosilane. A micropallet 262 on an array with virtual walls was released by a single pulse. For pallets less than 50 μm in height with an interpallet spacing of greater than 30 μm, aqueous solution filled the gap vacated by the pallet as depicted by an asterisk in FIGS. 26C and D. By moving the microscope stage, micropallets could be sequentially released while adjacent micropallets remained attached to the glass surface as shown in FIG. 26E. Over 100 pallets were released without detachment of pallets adjacent to the targeted pallet. When pallets of greater than 75-μm height (50-μm side, 30-μm interpallet spacing) were detached, trapped air rather than aqueous solution filled in the site of the released pallet as shown in FIG. 26E. Under these conditions, the virtual walls were stable despite the removal of the pallet from the array.

To compare the energy required to release pallets surrounded by air to that for pallets surrounded by aqueous buffer, the probability of pallet release was measured for arrays with and without virtual walls with respect to the laser pulse energy as shown in FIG. 26B. The curves of the probability of pallet release versus laser energy were fitted to a Gaussian error function to determine the threshold energy (Ep) for micropallet release. Ep for micropallets with and without virtual walls was 1.9 and 1.5, respectively. Thus, the energy needed to release micropallets surrounded by air or aqueous buffer was similar. No release of adjacent pallets was observed in these experiments (n>100).

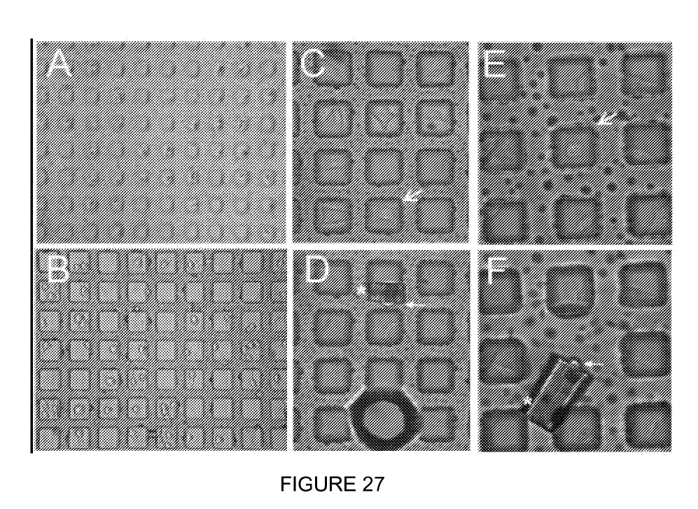

To further demonstrate laser-based release of cells/pallets surrounded by virtual walls, RBL and HeLa cells were cultured on micropallet arrays with virtual walls. Square pallets with 30-40 μm sides provided adequate surface area for 1-2 RBL or HeLa cells per pallet since the size of these cells is 25 μm (see FIG. 27A). Larger pallets (50-75 μm) could hold more cells due to the larger surface area (see FIG. 27B). The cells were localized to the pallet surfaces. Pallets with single cells were released by a focused laser pulse (2 μJ) (see FIGS. 27C and D). SU-8 possesses a density slightly greater than that of water so the released pallets settled back down onto the array. The pallet frequently remained within the field of view after release. When the pallet settled on its side, the cell could be visualized in profile attached to the top surface of the pallet (see FIGS. 27C-F). As for the arrays without cells, the fate of the entrapped air at the site of the released pallet depended on the array dimensions, pallet size, and interpallet spacing. The virtual wall at the site of the detached pallet was replaced by the aqueous buffer when the pallets were of limited height (see FIGS. 27C and D). In contrast, the virtual wall of air was stable when the pallets were of sufficient height (see FIGS. 27E and F). Following laser-based release, detached pallets were collected and examined to determine whether the cell remained on the pallet. For RBL cells, 94% of the collected pallets possessed cells (n=17). For HeLa cells, 93% of collected pallets (n=42) contained attached cells. The mechanical forces generated by the focused laser pulse at the glass-pallet interface were not sufficient to detach the majority of HeLa or RBL cells from the SU-8. In addition, the released cells appeared to have normal morphology by transmitted light microscopy, suggesting that the cells were viable.

To further establish the viability of released cells, HeLa cells cultured on pallet arrays were loaded with a viability indicator (calcein redorange AM) prior to release. Single cells on pallets were then released and immediately examined for retention of the dye. Over 90% of the HeLa cells (n=21) retained the dye, demonstrating that their plasma membrane was intact and the cells were viable. These data demonstrate that each pallet with its cell was releasable on demand using the focused beam of the laser. Most importantly, the cells remained viable following release of the pallet to which they were attached.

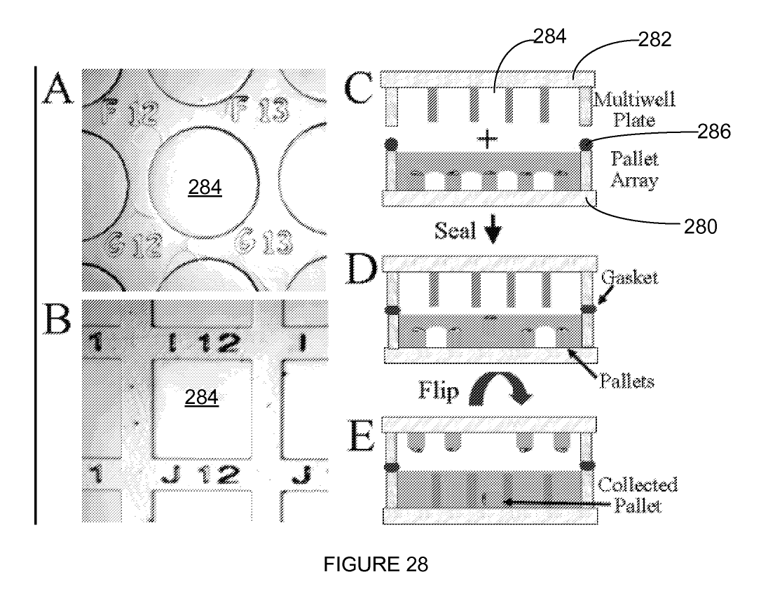

As depicted in FIG. 28, to enable efficient transfer and propagation of cells collected from a pallet array 280, a simple multiwell plate 282 was designed to mate with the pallet arrays 280. The plate 282 possessed 200 square or round wells 284 with dimensions of about 1 mm (see FIG. 28A or B) and was fabricated by casting PDMS against an SU-8 mold using a two mold process. The wells 284 were about 150 μm in depth and separated by walls 250 μm thick. Each well was alphanumerically labeled for identification. The multiwell plate 282 was circular with an outer diameter of 17 mm which matched the outer diameter of the chamber containing the pallet array (see FIGS. 28 C and D). Prior to use, the multiwell plate 282 was coated with sterile fibronectin (25 μg/mL in PBS) for 6 h at room temperature. The fibronectin adsorbed to the PDMS formed a suitable surface for cell attachment. Before pallet release, the collection plate 282 was placed on top of the pallet array 280 under sterile conditions in a tissue culture hood, and the plate 282 was sealed to the pallet array 282 using a sterile gasket 286 to prevent fluid leakage. During pallet selection and release, the array and multiwell plate remained sealed to maintain sterility of the interior of the unit. After pallet release, the collection plate/pallet array unit was carefully inverted so that the pallets and aqueous solution settled into the multiwell plate by gravity (see FIGS. 28D and E). The unit was then disassembled under sterile conditions, and the multiwell plate with the collected pallets was placed in a conventional tissue culture incubator. Typically many fewer pallets (<40) were released than the number of microwells in the collection plate. Thus, each microwell generally possessed 1 or 0 pallets. The numbering on the microwells permitted the cells to be followed over time within the collection plate.

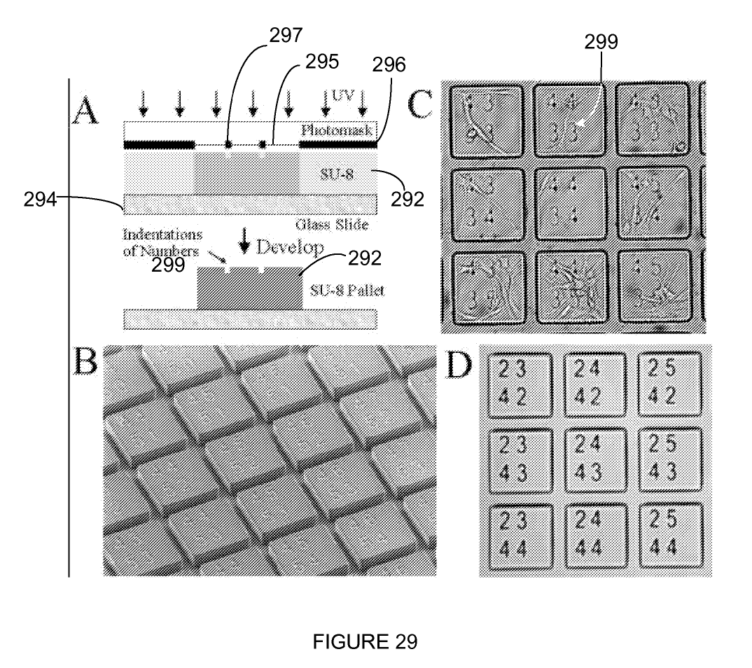

The multiwell plate efficiently collected released pallets and served as a convenient culture vessel for growth of clonal colonies. However, when multiple pallets were released and collected simultaneously, the pallets in the microwells could not be matched to their original location on the array. Thus, it was frequently difficult to track a cell from its position on the array, through the release process, and to its final position in a microwell on the collection plate. Matching a cell on the array to its clonal progeny will likely be important in future applications when cells are screened and selected for their specific properties. To track a pallet throughout the screening, release, and collection process, a 4-digit number 299 (see FIGS. 29 B-D) was inscribed on the surface of each pallet. Each pallet in an array received a unique number. The numerical code was created by placing numbers 297 (2 μm in width) in the clear regions 295 of the photomask 296 used to fabricate the pallets 292 (see FIG. 29A). During UV exposure to cross-link the SU-8 coated on a plate 294, the numbers blocked the UV light only on the top surface of SU-8. UV light diffused around the thin lines due to the small size of the numbers. As a result, only a shallow layer (2-5 μm deep) of uncured SU-8 was present below the numbers. This uncured SU-8 was dissolved during development, leaving indentations 299 in the surface of the pallet 292 (FIGS. 29B and D). The advantage of this approach is that it does not alter the fabrication process. The depth of the notches can be controlled by varying the UV exposure time. The numbers on the pallet were read following the growth of cells on the pallet by focusing below the layer of cells (FIG. 29C). One disadvantage of the encoding system was that the pallets must be of sufficient size for the four numbers. In order to be easily read, each number was 35-40 μm high and 15-20 μm wide so that pallets typically g75 μm wide were needed for these experiments. Pallets of this size or larger are expected to be of utility in a wide range of applications, particularly when small colonies of cells are selected, released, and collected.

While the invention is susceptible to various modifications, and alternative forms, specific examples thereof have been shown in the drawings and are herein described in detail. It should be understood, however, that the invention is not to be limited to the particular forms or methods disclosed, but to the contrary, the invention is to cover all modifications, equivalents and alternatives falling within the spirit and scope of the appended claims.

What is claimed:

1. A method of manufacture for creating a plate of releasable pallets comprising the steps of
coating a plate with a material that releaseably adheres to the plate, and
selectively removing portions of the material resulting in the creation of rigid pallets releasably adhered to the surface of the plate.

2. The method of claim 1 wherein the material comprises one or more photosensitive polymers.

3. The method of claim 2 wherein the step of selectively removing includes exposing the one or more photosensitive polymers to light.

4. The method of claim 3 wherein the exposing step includes passing the light through a mask.

5. The method of claim 1 further comprising the step of coating the material with a protective layer, and wherein the step of selectively removing includes patterning the protective layer, and etching or eroding the material through the protective layer to form rigid pallets releasably adhered to the surface of the plate.

6. The method of claim 1 further comprising the step of using a stencil to protect portions of the material from an eroding process, and wherein the step of selectively removing includes eroding the material unprotected by the stencil resulting in rigid pallets releasably adhered to the surface of the plate.

7. The method of claim 5 wherein a stencil is used to put a second material on the first in order to provide a temporary protective layer on the first material.

8. The method of claim 1 wherein the step of selectively removing the material includes using a laser to create rigid pallets releasably adhered to the plate.

9. The method of claim 8 wherein light from the laser is passed through a mask or stencil.

10. The method of claim 8 wherein laser energy from the laser is modulated to perform partial etch on the material, resulting in 3-D shapes.

11. The method of claim 1 wherein the step of selectively removing the material includes using a mechanical tool.

12. The method of claim 11 wherein the mechanical tool is connected to a computer.

13. The method of claim 1 further comprising a step of reforming the material using a mold.

14. The method of claim 13 further comprising the step of cleaning the plate containing the molded material to remove residue.

15. The method of claim 14 wherein the molded material is reheated and remolded to create predetermined shapes.

16. The method of claim 1 further comprising the step of modifying the surfaces of the rigid pallets on the plates.

17. The method of claim 16 wherein the modifying step includes applying one or more chemicals to the pallets.

18. The method of claim 17 wherein the chemicals are in liquid or vapor form.

19. The method of claim 17 further comprising the step of first applying a primer to the surface of the pallets in order to promote or resist surface modification.

20. The method of claim 16 further comprising the step of first applying light or radiation to promote or resist the formation of a surface coating.

21. The method of claim 20 wherein the light or radiation is passed through a mask or stencil.

22. The method of claim 16 further comprising the step of first changing the roughness of the surface of pallets to promote or resist the formation of a surface coating.

23. The method of claim 17 wherein the chemicals are brought in contact to the pallets using a second plate that holds the chemicals.

24. The method of claim 17 wherein the chemicals are brought in contact to the pallets under high pressure conditions.

25. The method of claim 17 wherein the chemicals are brought in contact to the pallets under low pressure conditions.

26. The method of claim 17 wherein the chemicals are brought in contact to the pallets using a machine dispensing systems.

27. The method of claim 17 wherein the chemicals are brought in contact to the pallets through a stencil.

28. A method for creating a cassette containing plate of pallets comprising the steps of
using a first process to form a cassette, and using a second process to form a plate of pallets.

29. The method of claim 28 wherein the cassette is adapted to hold the plate of pallets.

30. The method of claim 28 further comprising the step of bonding the plate of pallets to the cassette.

31. The method of claim 28 further comprising the step of attaching the plate of pallets to the cassette by friction or pressure.

32. The method of claim 28 further comprising the step of attaching the plate of pallets to the cassette using magnets.

33. The method of claim 28 wherein the cassette comprises multiple wells.

34. The method of claim 33 wherein a plate of pallets is attached in one of more of the multiple wells.

35. The method of claim 33 wherein one or more separate plates of pallets is placed within one or more wells in the multi-well cassette.

36. The method of claim 35 wherein a separate one of the one or more plates of pallets is placed in the cassette to be accessible through two or more openings in the wells of the multi-well cassette.
